(19) United States
(12) Patent Application Publication
(10) Pub. No.: US 2005/0170658 A1
(43) Pub. Date: Aug. 4, 2005

(54) Methods for preparing ball grid array substrates via use of a laser

(76) Inventor: Frank L. Hall, Boise, ID (US)

Correspondence Address: TRASK BRITT, P.O. BOX 2550, SALT LAKE CITY, UT, 84110, US

(21) Appl. No.: 11/098,161

(22) Filed: Mar. 25, 2005

Related U.S. Application Data
(63) Continuation of application No. 09/863,676, filed on May 21, 2001.

(51) Int. Cl. H01L 21/302; H01L 21/00; H01L 21/44; H01L 21/48; H01L 21/461; H01L 21/50; H01L 21/311

(52) U.S. Cl. 438/708; 438/106; 438/694

(57) ABSTRACT

The present invention relates to the use of a laser to remove surface contamination and oxidation from a ball grid array substrate. The laser etching can be configured to cover the entire substrate or pinpointed to the epoxy molding compound/solder resist (EMC/SR) interfaces. Additionally, a laser can be used to roughen the surface of a substrate to provide better adhesion when attaching the die to the substrate.

### CROSS-REFERENCE TO RELATED APPLICATION

This application is a continuation of application Ser. No. 09/863,676, filed May 21, 2001, pending.

### BACKGROUND OF THE INVENTION

Field of the Invention

The present invention relates to the use of a laser to remove surface contamination and oxidation from a ball grid array substrate and to promote adhesion of material for molding operations and other operations. The laser etching can be configured to cover the entire substrate or focused on local areas of the substrate, such as laser etching being pinpointed to the epoxy molding compound/solder resist (EMC/SR) interfaces.

Semiconductor packages are generally fabricated by mounting and electrically connecting the semiconductor die (also known as “semiconductor device”) to a carrier substrate appropriate for the chip type and the subsequent use of the package. For example, ball-grid-array (BGA), chip-on-board (COB), board-on-chip (BOC), chip-scale or leads over chip (LOC) mounting arrangements may be made on printed circuit board strips, tape frames and other carrier substrates known in the art. After mounting the semiconductor die to the substrate, the hybrid combination of the components are electrically connected by wire bonding, conductive adhesives, solder reflow or other connections known in the art. The package is then encapsulated for protection from various atmospheric ailments. Often the package becomes contaminated or oxidized due to atmospheric contaminants.

During the fabrication of the semiconductor package, a masking material (also known as resist) is used to enhance selectivity on both the semiconductor die and the circuits on the substrate. Resist plays a major role in the lithography process for fabrication of semiconductor devices in which the sizes, as well as the positions of the transistors, resistors and interconnects, are precisely determined on a wafer and fabricated. With the use of a patterned resist, selective etching and impurity doping can be performed. Thus, the resist is not part of the structure itself, but merely a masking material used for either the semiconductor die or the circuitry on the substrate to which the semiconductor die is attached. After the resist has been employed, a removal process is undertaken to remove the resist without damaging the fabricated semiconductor package.

One method of removing a resist layer consists of using reactive plasma etching. The plasma etching method suffers from drawbacks, such as incomplete removal of photoresist and resist popping. As a result, damages occur due to charges, currents, electric-field-induced UV radiation, contamination (such as alkali ions, heavy metals, and particulates), and elevated temperatures. Since plasma etching often leaves residues, a wet strip must follow to complete the stripping process. In many cases, to avoid alkali and heavy metals contamination, the plasma etching is stopped before the endpoint, and the wafer is transferred to a wet bath.

The wet bath also has drawbacks. Disadvantages associated with this method include solution concentrations that change with the number of wafers being stripped, thus affecting stripping quality and throughput; accumulation of contaminants in the baths, which drastically affects yield; and severely corrosive and toxic solutions that impose high handling and disposal costs and create serious safety considerations. Other problems are due to mass transport and surface tension associated with the solutions. For deep submicron technologies, the solutions cannot circulate and tend to accumulate within the patterned structure. This situation is intolerable, as it contaminates the wafer with foreign materials that can lead to drastic yield losses. All of these problems become even more critical for larger wafers. Also, such contaminants are present on the substrates used to mount the semiconductor die for a packaged assembly from the formation of the circuitry thereon using similar type processes.

Lasers may also be used in the manufacture of semiconductor die and substrates to remove resist. Currently, lasers are used in the applications of microelectronic fabrication, such as substrates and resistors. Lasers are widely used for trimming both thick and thin film resistors, for scribing wafers, for hole drilling in substrates, for welding of hermetically sealed packages and for stripping insulation from wires. The marking of silicon wafers with identification numbers has also become well established. In all these applications, lasers have become established production tools, replacing earlier technology for many applications.

A variety of different types of lasers are used in electronic fabrication. The use of the CO₂ and the infrared Nd:YAG lasers in electronic processing applications is well established; these lasers have been used for many years for applications such as trimming and drilling. Green and ultraviolet lasers may be focused to a smaller spot than the infrared devices and they may be chosen when a small focal diameter is desired. The use of ultraviolet lasers is relatively new, especially the excimer and frequency-tripled and -quadrupled ND:YAG lasers. These lasers have become more mature and reliable and they now present viable options for electronic processing. They offer the attractive feature of very high absorption in many materials of interest. Lasers have reached production status for a variety of applications in the electronics industry. One of the most significant is the trimming of resistors. This can significantly increase the yield in the processing of resistive elements.

There are numerous teachings relating to removing a resist layer from the surface of a substrate. For example, U.S. Pat. No. 4,789,427 to Fujimura et al., provides a method for removing a resist on a semiconductor device, including the steps of: removing the resist on a layer formed on a semiconductor substrate having a functional region, in a direction of the thickness thereof by a predetermined thickness by applying plasma processing; and removing the remaining resist by applying a chemical process.

In U.S. Pat. No. 5,200,031 to Latchford et al., disclose a process for removing photoresist remaining after a metal etch, which also removes or inactivates a sufficient amount of any remaining chlorine-containing residues, in sidewalls residues remaining from the metal etch step, to inhibit corrosion of the remaining metal or metals. The process includes a reducing step using NH₃ associated with a plasma followed by a subsequent stripping step using either O₂, or a combination of O₂ and NH₃ gases, and associated with a plasma.

More recent patents have begun to use lasers to remove marks from the substrate. U.S. Pat. No. 5,597,590 to Tanimoto et al. discloses a process in which a substrate such as a wafer is fixed upon a turntable, and then the alignment mark portions are removed with a sensitizing light beam that is projected to the thin film layer. Tanimoto et al. disclose that rotating the substrate has the advantage of causing the flying splinters of the thin film to fly off to the outer side radially due to the centrifugal force and making it difficult to cause the splinters to remain on the substrate surface. It is to be noted that in order to locally remove the resist layer, a photo etching method requiring no post developing operation may be used so that a high-energy ultraviolet light beam, such as an excimer laser, is projected onto the resist layer to break the molecular bond of the resist.

In U.S. Pat. No. 5,686,211 to Motegi et al., a method for removing a thin film layer covering the surface of a substrate, such as a semiconductor wafer is disclosed. Specifically, Motegi et al. disclose a method wherein a beam of energy, such as an excimer laser, is used to remove the resist material from the alignment marks.

Also, in U.S. Pat. No. 6,009,888 to Ye et al., a wafer is immersed in a liquid bath comprising peroxydisulfate, hydrochloric acid and water and then irradiating the photoresist pattern and polymer layer with a UV laser.

After resist is removed, it is well-known in the art that a critical step in the semiconductor device fabrication process is the encapsulation of semiconductor dice and their interconnections. The encapsulation or “sealing” of a semiconductor die and its wire bond interconnections within a “package” of plastic or other moldable material serves to protect their materials and components from physical and environmental stresses, such as dust, heat, moisture, static electricity, and mechanical shocks.

In a typical encapsulation process for surface-mounted semiconductor dice, a conductive substrate strip, with mounted and wire bonded semiconductor dice placed along the length of the strip, is placed in the lower mold plate of a “split cavity” mold comprising an upper and lower member. The upper and lower members of the mold are frequently referred to a “platens” or “halves.” With the upper mold platen raised, the conductive substrate strip is positioned on the lower mold platen such that the component portions to be encapsulated are in registration with multiple mold cavities formed in the lower mold platen. The mold is closed when the upper platen is lowered onto the lower platen. When the mold is closed, a peripheral portion of the conductive substrate strip is typically compressed between the upper and lower platens to seal the mold cavities in order to prevent leakage of liquified plastic molding compound. The force required to compress the platens together is generally of the order of tons, even for molding machines having only a few mold cavities.

Accordingly, what is needed in the art is a method of cleaning interfaces using a laser. Furthermore, a method of removing a resist layer wherein the substrate can be encapsulated immediately thereafter to prevent contamination or future oxidation is needed.

### BRIEF SUMMARY OF THE INVENTION

The present invention envisions a resist removal method comprising a substrate having a surface wherein resist is formed on at least a portion of the surface and a laser is provided to remove the resist from the substrate. The present invention also encompasses a method of fabricating a semiconductor device comprising a substrate having a surface wherein resist is formed on at least a portion of the surface, laser etching the surface of the substrate and encapsulating the substrate in a mold. The present invention also pertains to the cleaning of contaminants on a substrate. Additionally, the present invention teaches a method of enhancing the adhesion of a compound to the substrate surface by roughening the surface of the substrate.

### BRIEF DESCRIPTION OF THE SEVERAL VIEWS OF THE DRAWINGS

FIG. 1 is a flow chart showing the automolding process with laser etching incorporated therein;

FIG. 2 depicts a laser processing system as one embodiment of the present invention;

FIG. 3 is a top view of a ball grid array substrate/tape outline for forming a ball grid array package having circuit traces fanning-out to provide peripherally located test pads corresponding to a thin small outline package in accordance with the present invention;

FIG. 4 is a top view of a second ball grid array substrate/tape outline for forming a ball grid array package having circuit traces fanning-out to provide peripherally located test pads corresponding to a thin small outline package in accordance with the present invention; and

FIG. 5 is a top view of a COB package interposer.

### DETAILED DESCRIPTION OF THE INVENTION

The present invention embodies the use of a laser to remove surface contamination and oxidation from the solder resist layer of a semiconductor system. The laser etching can be performed either alone or as an addition to an automolding system.

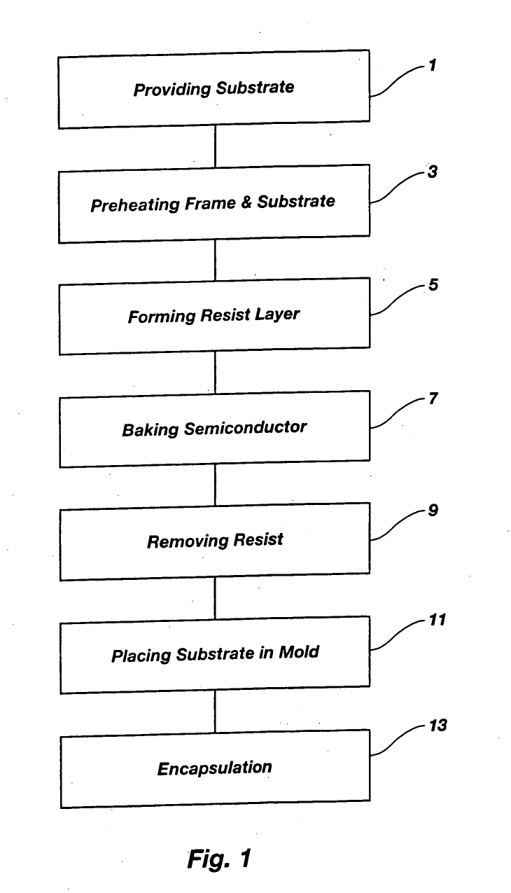

Illustrated in drawing FIG. 1 is a schematic portrayal of laser etching being performed on an automolding system. Step 1: First, the semiconductor substrate is loaded into the automolding system. Step 3: The bake modules are used to preheat the frame in order to drive off water vapor from the surface before spin-coating photoresist material onto the surface of the wafer. Step 5: The photoresist is then coated on the semiconductor substrate, thereby forming a photoresist layer. The photoresist layer is patterned by photolithography, forming a resist layer which will serve as a mask for forming a well region. Step 7: The wafer is then baked following the application of the photoresist in order to harden, or cure, the photoresist coating. Step 9: Portions of the resist layer are irradiated with electromagnetic radiation from a laser, which may comprise a carbon dioxide laser, an ultra violet laser, a Nd:YAG laser, a Nd:YLF laser, an excimer laser, or any other type of laser suitable for use in cutting or removing a resist layer. Additionally, a laser may be used to scan the substrate for irregularities so that the resist can be pinpointed for removal. The laser may also remove contamination and oxidation from the substrate. Step 11: The substrate is then placed in a mold prior to encapsulation. Step 13: The molding compound is then allowed a curing period, where it subsequently hardens to encapsulate the conductive substrate and the devices attached to it. Air is expelled from each cavity through one or more runners or vents as the plastic melt fills the mold cavities. Following hardening by partial cure of the thermoset plastic, the mold plates are separated along the parting line and the encapsulated semiconductor devices are removed and trimmed of excess plastic which has solidified in the runners and gates. Additional thermal treatment may complete the curing of the plastic package. The shape of the mold cavities and the configuration of the conductive substrate determine the final shape of the semiconductor package.

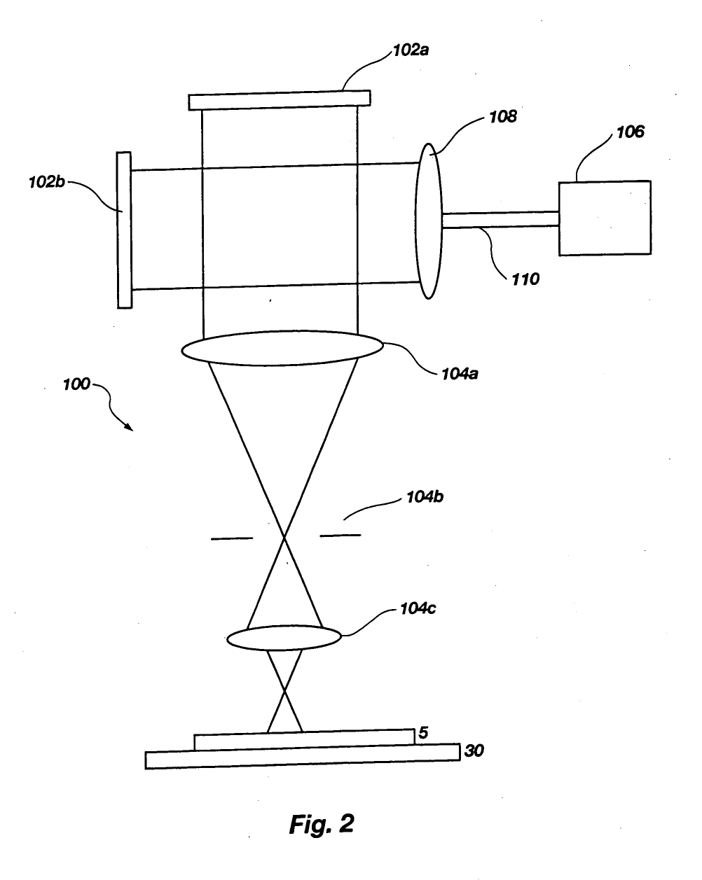

Illustrated in drawing FIG. 2 is an embodiment of the invention. The device 100 includes a plane light modulators 102a and 102b and a light source 106. The light 110 emerging from the light source 106 is projected onto the plane light modulators 102a and 102b via a beam forming and transmission unit 108. There may be more than one transmission unit 108 used to form the beam of light 110. The light reflected through the plane light modulators passes into an imaging optical system 104a, 104b, 104c and falls upon an exposed region of resist 5 attached to a substrate 30.

An Nd:YAG laser may be used in the process of the present invention. However, a CO₂ or excimer laser may also be used. Nd:YAG lasers are available in output from a few milliwatts to as high as a kilowatt in power. An advantage of Nd:YAG laser processing is its shorter wavelength; consequently, because of the dependency of the material's emissivity on the wavelength, energy is absorbed by the material more readily than with the CO₂ laser, and a lower energy can be used for welding, allowing greater control of the heat input. The wavelength of the Nd:YAG laser can range from 250 nm to 1200 nm. The output of an Nd:YAG laser is most often of 1064 nm wavelength. The active medium is an Nd:YAG laser rod. It is optically pumped by a continuous-pumping lamp and is placed between two external mirrors that form the optical cavity for the laser beam.

The optical cavity of the Nd:YAG laser usually consists of two mirrors mounted separately from the laser rod. Several cavity configurations may be used, but all employ at least one spherical mirror. Both long radius and long radius hemispherical cavities are commonly employed. In some systems, shaping of the beam within the cavity is desirable, and two mirrors with different radii of curvature are used. The HR mirror has a reflectivity of about 99.9% and the output coupler transmission varies from less than one percent on small lasers to about eight percent on larger ones. The optical cavities of Nd:YAG lasers are often equipped with an adjustable or interchangeable aperture for selection of multimode or TEM₀₀ mode operation.

A most critical subsystem of the laser is the cooling system. Without adequate cooling, the laser seals, pumping cavity, lamps, and the rod itself would be quickly destroyed by overheating. Lasing in Nd:YAG is most efficient when the temperature is lowest. Thus, cooling systems are designed to produce the lowest practical system operating temperature.

Another one of the embodiments of the present invention is illustrated in drawing FIG. 2 using an excimer laser. Excimer lasers generate laser light in ultraviolet to near-ultraviolet spectra, from 0.193 to 0.351 microns. Since excimer lasers have very short wavelengths, the photons have high energy. This results in reduced interaction time between laser radiation and the material being processed, therefore the heat affected zone is minimized. The above feature makes it ideal for material removal applications. They are used to machine solid polymer workpieces, remove polymer films from metal substrates, micromachine ceramics and semiconductors, and mark thermally sensitive materials. They are also used in surgical operations. Processing using excimer lasers is proved to have higher precision and reduced heat damage zones compared with CO₂ and Nd:YAG lasers.

Excimer lasers are said to be capable of “laser cold cutting.” Normally when CO₂ and Nd:YAG lasers are used for material removing, the energy is transformed from optical energy to thermal energy, the material is heated to melt or vaporize, then material changes from solid state to liquid or gaseous state. Excimer lasers can remove material through direct solid-vapor ablation. The incident photon energy is high enough to break the chemical bonds of the target material directly, the material is dissociated into its chemical components, and no liquid phase transition occurs in this process. This chemical dissociation process has much minimized heat effects, compared with the physical phase change process.

For example, vision systems, such as PRS, can be used to examine structural defects such as broken leads, dendrite growth, solder resist irregularities, oxide contamination, corrosion, etc. In this step, the vision system will typically compare pictures of lead frame fingers, bond pads, and other features on and around the individual semiconductor die sites to a predetermined known good template. Electrical testing can also be accomplished, for example, by using various automated or other test equipment, including curve tracer testing, test probes, RF testing, and the like. Tests screening for intermittent failures, such as high temperature reverse-bias (HTRB) tests, vibration testing, temperature cycling, and mechanical shock testing, etc. are also contemplated by the present invention, as well as tests for solderability, microcorrosion, noise characterization, electromigration stress, electrostatic discharge, plating defects, etc. The results of the different tests are fed into a computer, compiled, and correlated with individual semiconductor die sites on a particular mounting substrate array.

To prevent contamination from particles typically found in the smoke resulting from a conventional laser ablative process, filtered air may be forced over the substrate.

The beam of light may be scanned over the surface of the bare semiconductor die or a partially packaged semiconductor die attached to a substrate in the requisite pattern, or can be directed through a mask, which projects the desired inscriptions onto the desired surface of the bare semiconductor die or partially packaged semiconductor die attached to a substrate. The surface or coating of the bare or packaged semiconductor die thus modified, the laser marking creates a reflectivity difference from the rest of the surface of the bare or packaged semiconductor die.

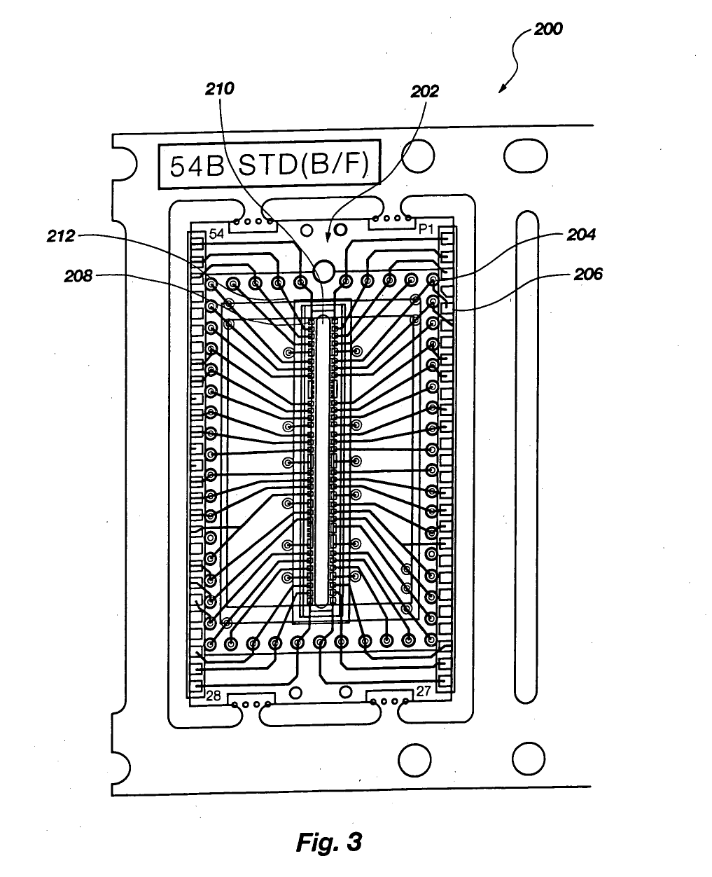

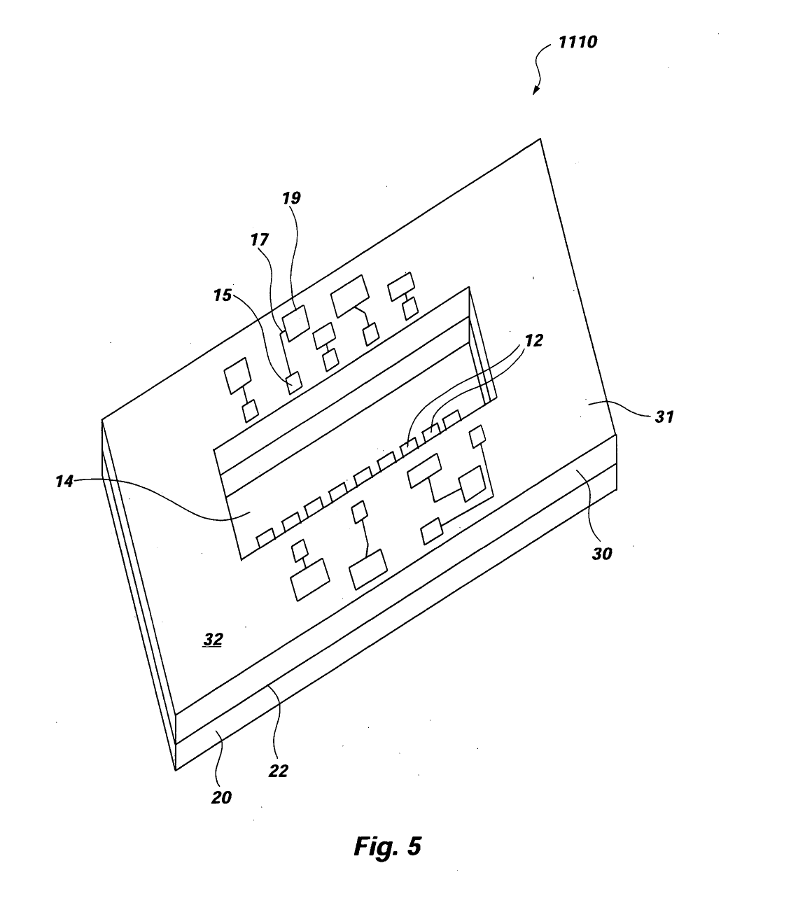

Preferably, a laser is used to remove contaminants and/or resist from a BGA substrate. Illustrated in drawing FIG. 3 is a substrate tape outline 200 showing an individual chip circuitry portion 202 having a preselected ball grid array arrangement. In drawing FIG. 3, individual chip circuitry portion 202 includes a ball grid array substrate which has been laid out so as to place solder balls and/or connective elements 204 about the periphery of what is to be the chip-scaled package with test contact pads 206 being further outwardly positioned opposite each other along two sides of what will be a chip package. The test contact pads 206 in drawing FIG. 5 have been prearranged to coincide with a thin small outline package pin-out configuration. Bond pads 208 located along aperture 210 are placed in electrical communication with selected respective solder balls and/or connective elements 204 by circuit traces 212. In turn, selected solder balls 204 are placed in electrical communication with test contact pads 206 so as to provide a continuous conductive path from a selected test contact pad 206 back to at least one selected bond pad 208.

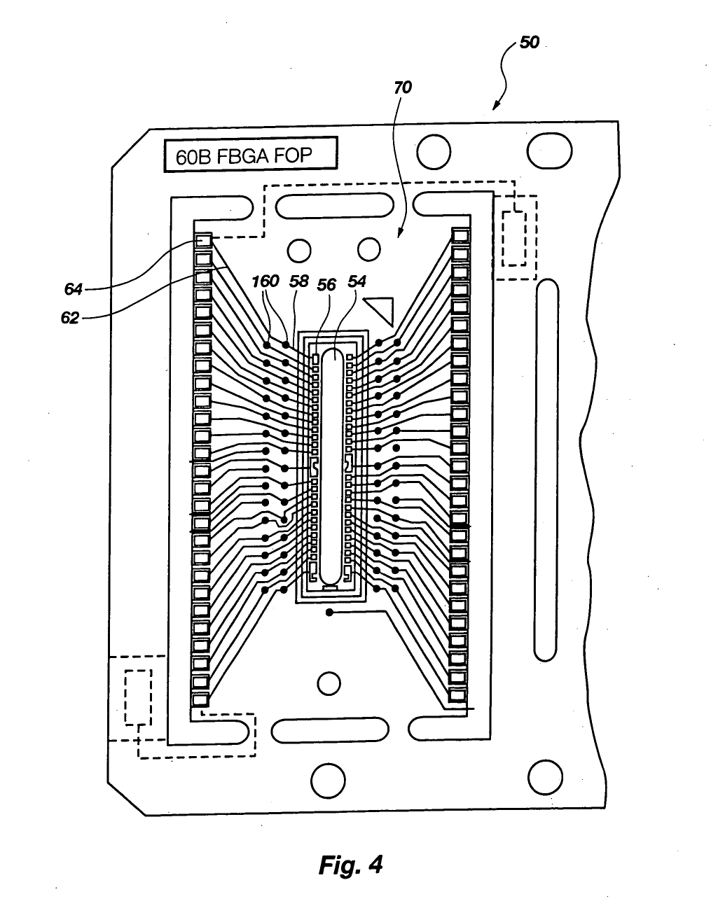

Illustrated in drawing FIG. 4 is a semicompleted BGA chip package which includes an aperture 54 having bond pads 56 located along opposing sides of the aperture 54. Bond pads 56 are selectively provided with an electrically conductive trace 58 that leads to a respective conductive element, solder ball or solder ball location 160. Selected conductive elements, or solder balls 160, are provided with a second circuit trace 62 leading to a respective test contact pad 64 located outwardly away from aperture 54 and solder balls 160. Test contact pads 64 are preferably arranged to fan-out in what is referred to as thin small outline package (TSOP), which is recognized as an industry standard.

As can be seen in drawing FIG. 4, individual chip circuitry portion 70 includes various circuit traces 58 and 62 which interconnect bond pads 56 to solder balls 160 and which further interconnect solder balls 160 to peripherally located test contact pads 64 and are able to be easily routed around any solder balls 160 in a somewhat serpentine fashion to circumvent one or more particular solder balls that would otherwise physically block the circuit from reaching its respective destination. This particular characteristic of being able to route circuit traces as needed around intervening solder balls 160, or alternative connective elements used in connection with, or in lieu of solder balls, allows great versatility in that solder ball grid arrays having virtually any feasible number of solder balls arranged in any feasible pattern could be used and need not be restricted to the exemplary column arrangement as shown in drawing FIG. 4. It should be appreciated that although substrate tape outline 50 provides a convenient, cost efficient method of providing the desired circuit traces and ball grid array on a selected substrate, alternative methods to apply circuit traces to a substrate can be used. For example, circuit layers including circuit traces, bond pads, solder balls, or contact elements, and/or test contact pads could be screen printed onto one or both faces of a substrate. Furthermore, multiple layers of circuit layers can be disposed upon not only the exposed surfaces of the supporting substrate, but circuit layers could be “sandwiched” or laminated within the substrate by circuit layer lamination methods known in the art if so desired. Resist can be placed on any of these features and can be removed via a process with the use of a laser.

Described in drawing FIG. 5 is a board-on-chip assembly 1110. A packaged, flip-chip type semiconductor device incorporating teachings of the present invention, as shown in drawing FIG. 5, has conductive structures protruding therefrom in a ball grid array pattern and includes a semiconductor die 20 and a substrate, which is also referred to herein as an interposer 30. The interposer 30 may be roughened by a laser to increase the surface area for better attachment to the semiconductor die 20.

The interposer 30 includes a substantially planar substrate 31 that may be formed from any suitable material, such as resin (e.g., FR-4 resin), plastic, insulator-coated semiconductor material (e.g., silicon oxide-coated silicon), glass, ceramic, or any other suitable, electrically insulative or dielectric-coated material, which may be positioned over the active surface 22 of the semiconductor die 20.

As shown, the interposer 30 includes an aperture or slot 14 formed therethrough for exposing the bond pads 12 of a semiconductor device 20 over which the interposer 30 is to be positioned. Contact areas 15 are carried upon a top side 32 of the interposer 30. Preferably, the contact areas 15 are located proximate to the slot 14 so as to facilitate the positioning of relatively short intermediate conductive elements through the slot 14, between the bond pads 12 of a semiconductor die 20 and the contact areas 15. As illustrated in drawing FIG. 5, a circuit trace 17 extends laterally from each contact area 15 to a corresponding terminal 19, which may also be carried upon the top side 32 of the interposer 30, electrically connecting each contact area 15 to its corresponding terminal 19. All of the above components may be covered with a resist layer which may be removed with the use of a laser.

While certain representative embodiments and details have been shown for purposes of illustrating the invention, it will be apparent to those skilled in the art that various changes in the invention as disclosed herein may be made without departing from the scope of the invention, which is defined in the appended claims.

1. A method for resist removal from a substrate having a surface having resist on at least a portion thereof for use in a system having a laser associated with a mold for a semiconductor device, the resist removed by the system before molding of said substrate in the system, comprising:
removing at least a portion of the resist from the substrate using the laser.

2. The method according to claim 1, further comprising:
flowing filtered gas over the surface having resist on at least a portion thereof while removing a portion of the resist from the substrate.

3. The method according to claim 1, wherein the laser comprises one of an Nd:YAG laser and an excimer laser.

4. The method according to claim 1, wherein the substrate comprises a ball-grid-array substrate.

5. The method according to claim 1, further comprising a vision system for detecting resist.

6. The method according to claim 4, wherein the vision system comprises:
providing a laser scanning system; and
detecting changes in a pattern of the substrate.

7. A method of fabricating a semiconductor device in a system including an automolding device, the method comprising:
providing a system having a laser for etching resist from a surface of a substrate;
providing a substrate having a surface;
forming resist on at least a portion of the surface;
laser etching the resist from at least a portion of the surface of the substrate; and
encapsulating the substrate.

8. The method according to claim 7, wherein the laser comprises one of an Nd:YAG laser and an excimer laser.

9. The method according to claim 7, wherein the substrate comprises a ball-grid-array substrate.

10. The method according to claim 7, further comprising a vision system for detecting resist.

11. The method according to claim 10, wherein the vision system comprises:
providing a laser scanning system; and
detecting changes in a pattern of the substrate.

12. The method according to claim 7, further comprising flowing a filtered gas over the substrate during etching the resist from at least a portion of the surface of the substrate.

13. The method according to claim 7, further comprising testing the substrate.

14. A method for resist removal from a substrate having a surface having resist on at least a portion thereof for use in a system having a laser associated with a mold for a semiconductor device, the resist removed in the system before molding of said substrate in the system, comprising:
removing at least a portion of the resist from the substrate using the laser.

15. The method according to claim 14, further comprising:
flowing filtered gas over the surface having resist on at least a portion thereof while removing a portion of the resist from the substrate.

16. The method according to claim 14, wherein the laser comprises one of an Nd:YAG laser and an excimer laser.

17. The method according to claim 14, wherein the substrate comprises a ball-grid-array substrate.

18. The method according to claim 14, further comprising a vision system for detecting resist.

19. The method according to claim 18, wherein the vision system comprises:
providing a laser scanning system; and
detecting changes in a pattern of the substrate.

20. The method of claim 14, further comprising testing the substrate.
